(19) United States
(12) Patent Application Publication
(10) Pub. No.: US 2006/0226467 A1
(43) Pub. Date: Oct. 12, 2006

(54) P-channel charge trapping memory device with sub-gate

(75) Inventors: Hang-Ting Lue, Hsinchu (TW); Min-Ta Wu, (US); Erh-Kun Lai, Hsinchu (TW); Yen-Hao Shih, (US); Chia-Hua Ho, (US); Kuang-Yeu Hsieh, Hsinchu (TW)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: Macronix International Co., Ltd.

(21) Appl. No.: 11/100,518

(22) Filed: Apr. 7, 2005

(51) Int. Cl. H01L 29/788

(52) U.S. Cl. 257/315

(57) ABSTRACT

A semiconductor device includes a semiconductor substrate. The semiconductor substrate includes a first inversion region, a second inversion region, and a channel region between the first inversion region and the second inversion region. The semiconductor device further includes a control gate over the channel region and at least one sub-gate over the first and second inversion regions, wherein the control gate does not extend over the at least one sub-gate.

### TECHNICAL FIELD

This invention is in general related to a memory device and, more particularly, to a novel flash memory device that utilizes sub-gates and replaces diffusion regions of the memory cells with inversion regions controlled by the sub-gates.

### BACKGROUND

Memory devices for non-volatile storage of information are widely used. Examples of such memory devices include read only memory (ROM), programmable ROM (PROM), erasable programmable ROM (EPROM), electrically erasable programmable ROM (EEPROM), and flash EEPROM. A flash memory generally refers to a flash EEPROM, which may be erased in blocks of data instead of one byte at a time.

A flash memory device generally includes an array of memory cells arranged in rows and columns. Each memory cell includes a MOS transistor structure having a gate, a drain, a source, and a channel defined between the drain and the source. The gate corresponds to a word line, and the drain or source corresponds to a bit line of the memory array. A conventional flash memory cell generally includes a trapping layer provided between the gate and the channel. The trapping layer may be a floating gate formed of polysilicon or a dielectric such as silicon nitride. When the gate, the drain, and the source of the memory cell are appropriately biased, charge carriers (electrons or holes) may be forced to tunnel into the trapping layer, which traps the carriers. As a result, the memory cell is programmed. The memory cell may be read or erased by applying different biases to the gate, the drain, and the source thereof.

### SUMMARY OF THE INVENTION

Consistent with embodiments of the present invention, there is provided a semiconductor device that includes a semiconductor substrate. The semiconductor substrate includes a first inversion region, a second inversion region, and a channel region between the first inversion region and the second inversion region. The semiconductor device further includes a control gate over the channel region and at least one sub-gate over the first and second inversion regions, wherein the control gate does not extend over the at least one sub-gate.

Consistent with embodiments of the present invention, there is also provided a memory device that includes a semiconductor substrate and a plurality of memory cells arranged in a plurality of rows each corresponding to one of a plurality of word lines and a plurality of columns each corresponding to one of a plurality of bit lines. Each memory cell includes a first inversion region of the semiconductor substrate, a second inversion region of the semiconductor substrate, a channel region defined as a portion of the semiconductor substrate between the first and second inversion regions, a control gate over the channel region, and at least one sub-gate over the first and second inversion regions, wherein the first inversion region and the second inversion region are along a direction of the corresponding one of the bit lines, and each word line connects the control gates of the memory cells in the same row. The memory device further includes a plurality of diffusion regions, wherein each bit line includes two of the diffusion regions at the ends of the corresponding bit line.

Consistent with embodiments of the present invention, there is further provided a method of operating a memory cell that includes at least one of resetting the memory cell, erasing the memory cell, programming the memory cell, and reading the memory cell. The memory cell is formed on an n-type semiconductor substrate, and includes a first inversion region and a second inversion region in the semiconductor substrate, a channel region in the semiconductor substrate between the first inversion region and the second inversion region, a control gate over the channel region, and at least one sub-gate over the first and second inversion regions, wherein the control gate does not extend over the at least one sub-gate.

Consistent with embodiments of the present invention, there is provided another method of operating a memory device including a plurality of memory cells that includes at least one of resetting the memory device, erasing the memory device, programming a selected memory cell, and reading a selected memory cell. The memory device is formed on an n-type semiconductor substrate. The plurality of memory cells are arranged in a plurality of rows each corresponding to one of a plurality of word lines and a plurality of columns each corresponding to one of a plurality of bit lines, each memory cell including a first inversion region of the semiconductor substrate, a second inversion region of the semiconductor substrate, a channel region defined as a portion of the semiconductor substrate between the first and second inversion regions, a control gate over the channel region, and at least one sub-gate over the first and second inversion regions, wherein the first inversion region and the second inversion region are along a direction of the corresponding one of the bit lines, and wherein each word line connects the control gates of the memory cells in the same row, the memory device further including a plurality of diffusion regions, wherein each bit line includes two of the diffusion regions at the ends of the corresponding bit line.

Additional features and advantages of the invention will be set forth in part in the description which follows, and in part will be obvious from the description, or may be learned by practice of the invention. The features and advantages of the invention will be realized and attained by means of the elements and combinations particularly pointed out in the appended claims.

It is to be understood that both the foregoing general description and the following detailed description are exemplary and explanatory only and are not restrictive of the invention, as claimed.

### BRIEF DESCRIPTION OF THE DRAWINGS

The accompanying drawings, which are incorporated in and constitute a part of this specification, illustrate embodiments of the invention and, together with the description, serve to explain the features, advantages, and principles of the invention.

In the drawings,

FIG. 1 shows the cell structure of a p-type memory cell;

FIG. 2 shows the cell structure of a memory cell consistent with a first embodiment of the present invention;

FIGS. 3A-3D illustrate operations of the memory cell of FIG. 2;

FIG. 4A shows a plan view of a memory array consistent with a second embodiment of the present invention;

FIG. 4B shows a cross-sectional view of the memory array consistent with the second embodiment of the present invention along line A-A′ of FIG. 4A;

FIGS. 4C-4G illustrate operations of the memory array of FIGS. 4A and 4B consistent with the second embodiment of the present invention;

FIG. 5 shows a cross-sectional view of a memory cell consistent with a third embodiment of the present invention;

FIG. 6A shows a plan view of a memory array consistent with a fourth embodiment of the present invention;

FIG. 6B shows a cross-sectional view of the memory array consistent with the fourth embodiment of the present invention along line B-B′ of FIG. 6A;

FIGS. 7A-7C illustrate a manufacturing process of the memory cell consistent with the first embodiment of the present invention; and

FIGS. 8A-8B illustrate a manufacturing process of the memory cell consistent with the third embodiment of the present invention.

### DESCRIPTION OF THE EMBODIMENTS

Reference will now be made in detail to the preferred embodiments of the invention, examples of which are illustrated in the accompanying drawings. Wherever possible, the same reference numbers will be used throughout the drawings to refer to the same or like parts.

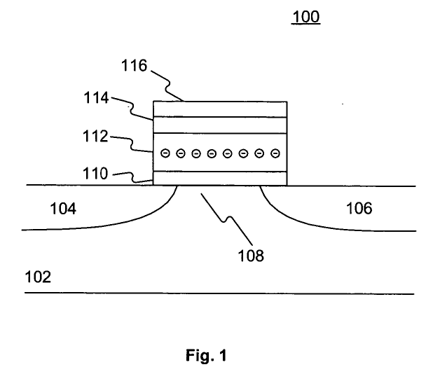

In memory devices utilizing carrier tunneling for programming and erasing operations, electron tunneling has proven to be more efficient than hole tunneling. Therefore, a memory cell formed of a p-type MOS transistor, which utilizes band-to-band tunneling induced hot electron injection (BTBTHE), is generally faster and requires lower power during programming, as compared to a memory cell formed of an n-type MOS transistor. One such p-type memory device utilizing BTBTHE is illustrated in FIG. 1.

In FIG. 1, a memory cell 100 is formed on an n-type semiconductor substrate 102 and includes two p-type diffusion regions 104 and 106, a channel region 108 between diffusion regions 104 and 106, a first insulating layer 110, a trapping layer 112, a second insulating layer 114, and a control gate 116. Memory device 100 is a p-type MOS transistor, with diffusion regions 104 and 106 respectively acting as the source and drain thereof. By applying appropriate biases to control gate 116 and diffusion regions 104 and 106, electrons may tunnel into and out of trapping layer 112, as a result of which memory cell 100 may be programmed or erased.

Trapping layer 112 is formed of a dielectric such as silicon nitride. Thus, when electrons tunnel into trapping layer 112, the electrons become relatively immobile. By controlling the biases on control gate 116, source 104, and drain 106, it is possible to control which part of trapping layer 112 the electrons tunnel into. Therefore, trapping layer 112 may be divided into two parts, a first bit adjacent to source 104 and a second bit adjacent to drain 106, each for the storage of one bit of information. The first bit and the second bit may be respectively programmed, read, or erased. For example, the first bit may be programmed by applying 5V to control gate 116, −5V to source 104, and 0V to drain 106.

Diffusion regions 104 and 106 of memory cell 100 are p⁺ regions, the formation of which may be difficult to control during the manufacturing process of memory cell 100. For example, when channel 108 is very short, lateral diffusion of boron ions could degrade the performance of memory cell 100.

Consistent with embodiments of the present invention, there are provided memory devices including memory cells with channel regions between inversion regions rather than between diffusion regions.

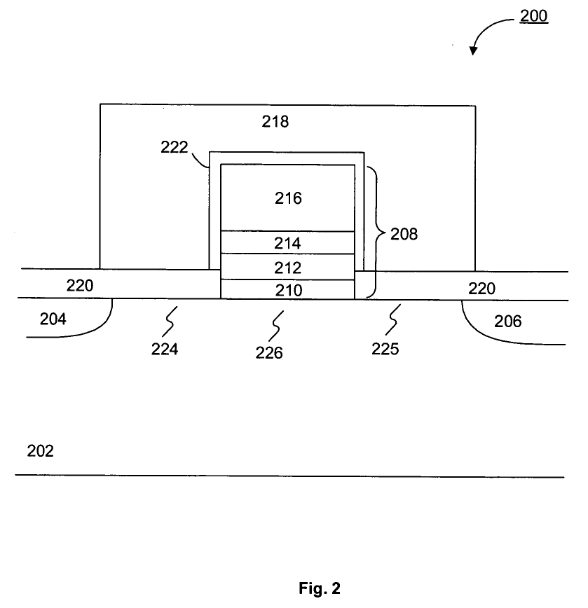

FIG. 2 shows the cell structure of an exemplary memory cell 200 consistent with a first embodiment of the present invention. Memory cell 200 is formed on a semiconductor substrate 202 including diffusion regions 204 and 206. Semiconductor substrate 202 may comprise any conventional semiconductor material, such as silicon. In one aspect, substrate 202 is doped with n-type impurities, and diffusion regions 204 and 206 are doped with p-type impurities.

Memory cell 200 includes a multi-layer gate structure 208 formed on semiconductor substrate 202. Gate structure 208 is between and spaced apart from diffusion regions 204 and 206. Gate structure 208 includes a first insulating layer 210, a trapping layer 212, a second insulating layer 214, and a control gate 216. First insulating layer 210, trapping layer 212, and second insulating layer 214 may constitute an ONO structure, wherein first insulating layer 210 comprises silicon dioxide, trapping layer 212 comprises silicon nitride, and second insulating layer 214 comprises silicon dioxide. Control gate 216 may comprise polysilicon, a metal, or metal silicide, or a combination thereof. For example, control gate 216 may comprise a combination of polysilicon and tungsten silicide (WSi).

Memory cell 200 also includes two inversion regions 224 and 225 and a channel region 226. Inversion region 224 is defined as the portion of semiconductor substrate 202 between gate structure 208 and diffusion region 204, inversion region 225 is defined as the portion of semiconductor substrate 202 between gate structure 208 and diffusion region 206, and channel region 226 is defined as the portion of semiconductor substrate 202 between inversion regions 224 and 225, i.e., below gate structure 208.

Memory cell 200 further includes a sub-gate 218 provided over inversion regions 224 and 225 and gate structure 208. Sub-gate 218 may comprise polysilicon, a metal, or metal silicide, or a combination thereof. Sub-gate 218 is electrically isolated from inversion regions 224 and 225 by a layer of gate dielectric 220, and electrically isolated from gate structure 208 by an insulating spacer 222. Gate dielectric 220 may comprise an oxide. Insulating spacer 222 may comprise an oxide or a nitride.

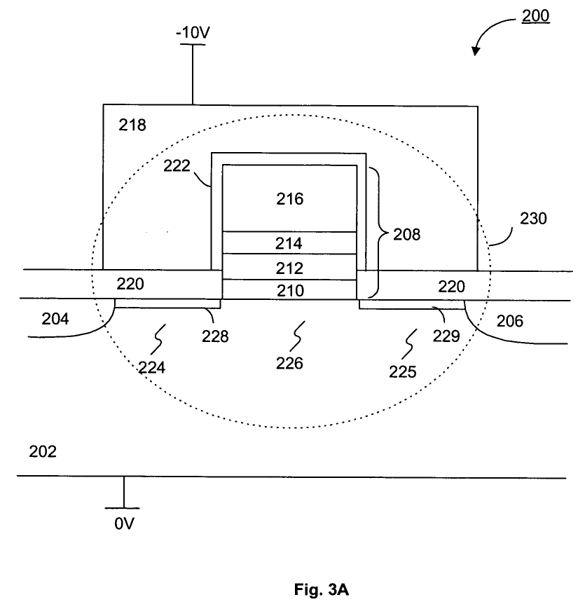

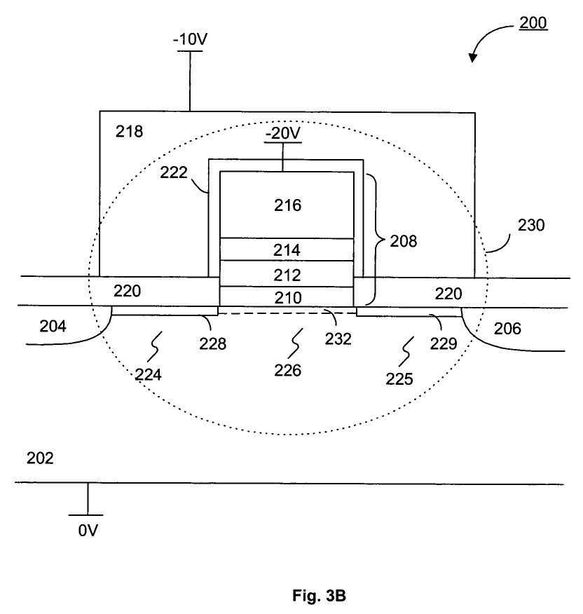

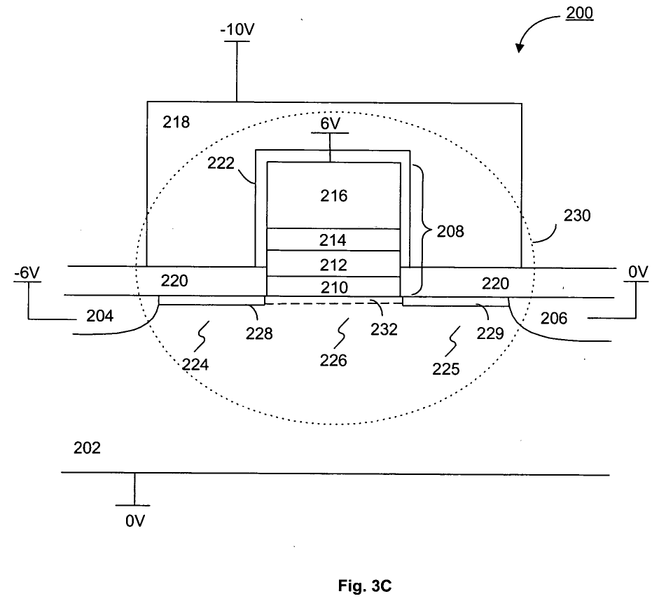

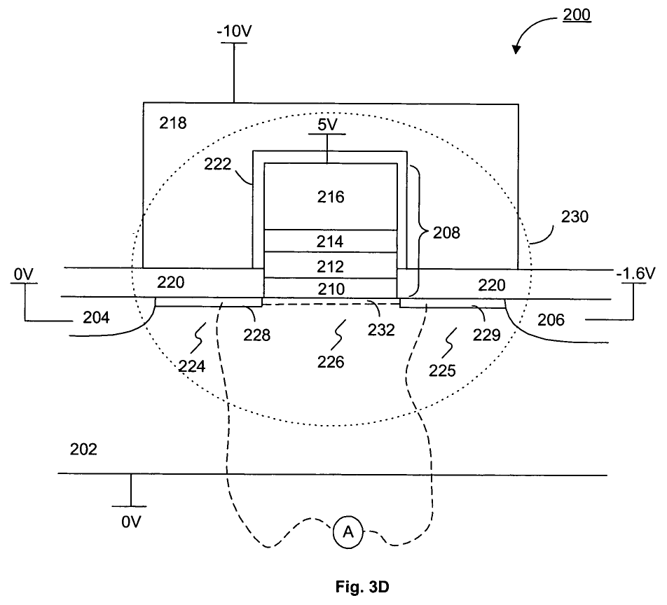

By applying appropriate biases to sub-gate 218 and semiconductor substrate 202, shallow p-type regions resulting from inversion may be formed in inversion regions 224 and 225. For example, in FIG. 3A, semiconductor substrate 202 is grounded and sub-gate 218 is biased at −10V. If the MOS structure comprising sub-gate 218, gate dielectric 220, and semiconductor substrate 202 has a threshold voltage V_{T0} (negative in sign), then when the bias on sub-gate 218 is lower than the bias on semiconductor substrate 202 by an amount greater than |V_{T0}|, inversion occurs in both inversion regions 224 and 225. In this case, holes accumulate near the surface of n-type semiconductor substrate 202 in inversion regions 224 and 225, and shallow p-type regions 228 and 229 are formed (FIG. 3A). Depending on the biases to sub-gate 218 and semiconductor substrate 202, the hole concentration in p-type regions 228 and 229 may be controlled. Particularly, a more negative bias on sub-gate 218 results in a higher hole concentration in p-type regions 228 and 229.

As shown in FIG. 3A, p-type regions 228 and 229 and gate structure 208 constitute a p-type MOS transistor 230, where shallow p-type regions 228 and 229 are the source and drain of MOS transistor 230. Because of trapping layer 212 in gate structure 208, MOS transistor 230 may be used to store information represented by charges trapped in trapping layer 212. For example, as shown in FIG. 3B, memory cell 200 may be erased or reset by applying a high negative voltage, e.g., −20V, to control gate 216, and grounding semiconductor substrate 202. This causes a strong vertical electric field to be created across gate structure 208. Under the strong electric field, two electron tunneling processes take place. In the first tunneling process, electrons tunnel from control gate 216, through second insulating layer 214, into trapping layer 212. In the second tunneling process, electrons tunnel from trapping layer 212, through first insulating layer 210, into semiconductor substrate 202. When a dynamic balance is reached between the two tunneling processes, memory cell 200 is reset. In one aspect, in the reset state, the concentration of electrons in trapping layer 212 is such that a p-type channel 232 exists in channel region 226 even when no biases are applied. As a result, in the reset state, the threshold voltage, Vₜₕ₋ᵣₑₛₑₜ, of MOS transistor 230 is positive, e.g., 4V, and MOS transistor 230 is a depletion-mode transistor, which is normally on even when no biases are applied. To turn off MOS transistor 230, the bias across control gate 216 and the source, i.e., p-type 228 or 229, V_{G}-V_{S}, must be greater than Vₜₕ₋ᵣₑₛₑₜ, where VG is the bias at control gate 216 and V_{S} is the bias at the source of MOS transistor 230.

To program or read memory cell 200, however, biases must be provided to the source and drain of p-type MOS transistor 230, i.e., p-type regions 228 and 229. Because shallow p-type regions 228 and 229 are conductive, they may be biased by providing biases to diffusion regions 204 and 206. For example, in FIG. 3C, memory cell 200 is programmed by biasing sub-gate 218 at a negative voltage, e.g., −10V, control gate 216 at a positive voltage, e.g., 6V, and diffusion region 204 at a negative voltage, e.g., −6V. Both diffusion region 206 and semiconductor substrate 202 are grounded. Thus, p-type regions 228 and 229 may be considered as being respectively biased at approximately −6V and 0V. Because of the large negative potential on p-type region 228, a deep depletion junction and, therefore, a strong electric field are generated between p-type region 228 and semiconductor substrate 202. Electrons tunnel from the valence band of p-type region 228 to the conduction band of semiconductor substrate 202, and are accelerated along channel region 226 by another electric field created by the bias difference between p-type regions 228 and 229. As the electrons are accelerated along channel region 226 and attain high energy, the vertical electric field due to the positive control gate bias “pulls” some of the electrons out of channel region 226 and the electrons are injected into trapping layer 212.

Under the biasing scheme of FIG. 3C, the accelerated electrons gain most of the energy in the neighborhood of p-type region 228 and tunnel into the left portion of trapping layer 212 that is adjacent to p-type region 228. Because trapping layer 212 is a dielectric layer (such as silicon nitride), the electrons are trapped in the left portion of trapping layer 212. As a result, the hole concentration in the left portion of channel region 226 is higher than when memory cell 200 is in the reset state, and MOS transistor 230 may be turned on even when a voltage bias greater than Vₜₕ₋ᵣₑₛₑₜ is applied to control gate 216 and diffusion region 204 is grounded. In other words, a local threshold V_{th-program} corresponding to a channel created in the left portion of channel region 226 is greater than Vₜₕ₋ᵣₑₛₑₜ. For example, V_{th-program} may be around 6˜7V. Thus, by appropriately biasing memory cell 200 and measuring a current through channel region 226, it may be determined whether memory cell 200 has been programmed in the manner of FIG. 3C. For example, referring to FIG. 3D, sub-gate 218 is biased at, e.g., −10V, control gate 216 at, e.g., 5V, diffusion region 204 at, e.g., 0V, and diffusion region 206 at, e.g., −1.6V. Semiconductor substrate 202 is grounded. Current through channel region 226 is then measured under these biasing conditions. Because Vₜₕ₋ᵣₑₛₑₜ <5V<V_{th-program}, a current is detected if memory cell 200 has been programmed under the biasing scheme of FIG. 3C, and no current is detected if memory cell 200 is not programmed or is in the reset state. This method of reading a memory cell is called “reverse read,” because the source and drain terminals of the memory cell are interchanged when the memory cell is programmed and read.

The biases on diffusion regions 204 and 206 may be switched in FIGS. 3C and 3D to respectively program and read the right portion of trapping layer 212. Thus, memory cell 200 is operated to store two bits of information, the first bit corresponding to the left portion of trapping layer 212, the second bit corresponding to the right portion of trapping layer 212, and the first bit and second bit may be programmed and read individually.

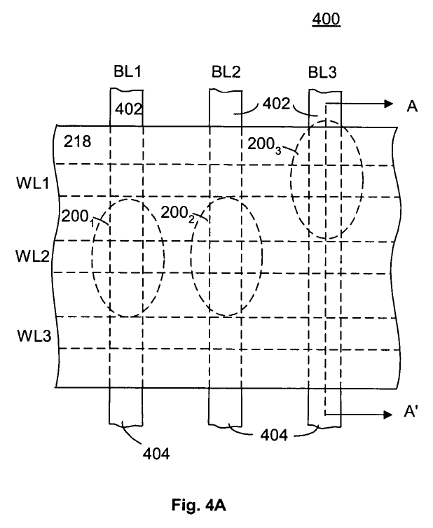

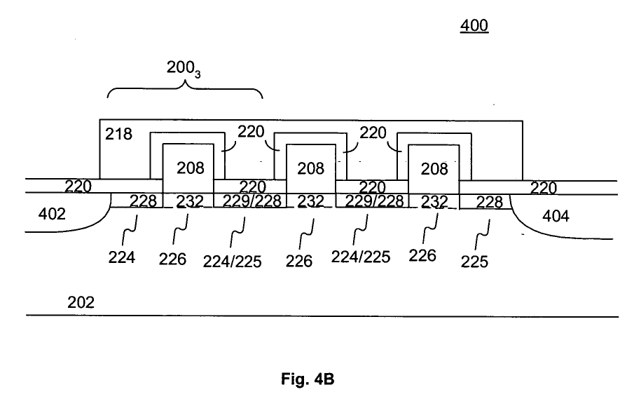

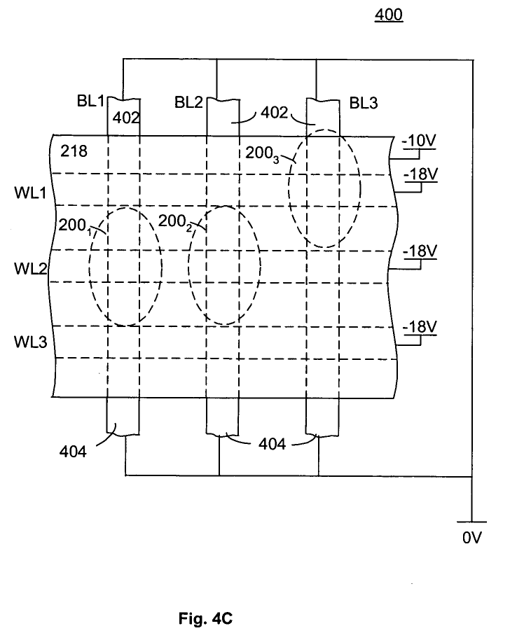

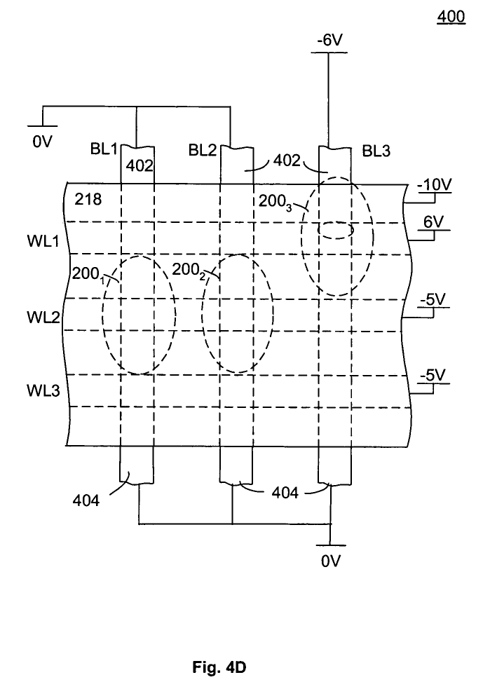

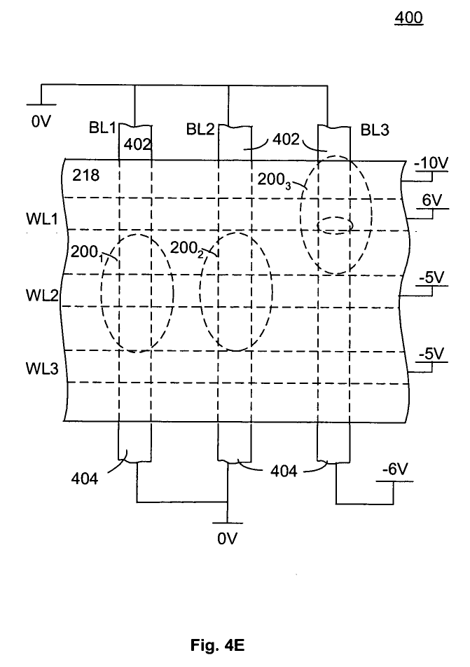

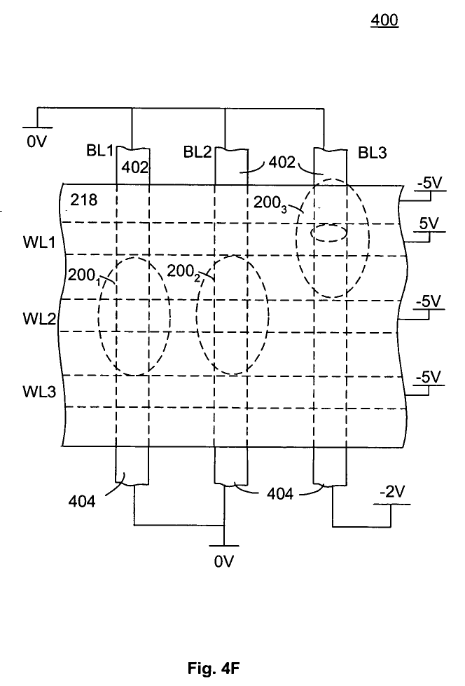

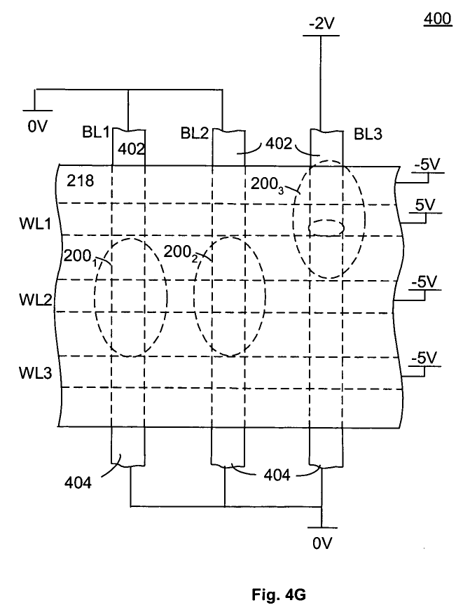

Consistent with a second embodiment of the present invention, a plurality of memory cells may be arranged to form a memory array. FIG. 4A is a plan view of a memory array 400 formed of a plurality of memory cells 200 (200₁, 200₂, 200₃, . . . ) arranged in a plurality of rows each corresponding to a word line WL (WL1, WL2, WL3, . . . ) and a plurality of columns each corresponding to a bit line BL (BL1, BL2, BL3, . . . ). FIG. 4B is a cross-sectional view of memory array 400 along line A-A′ of FIG. 4A. Gate structures 208 of memory cells 200 in the same row are connected together and constitute the corresponding word line WL. Each bit line includes two diffusion regions 402 and 404 at the ends thereof, and also includes inversion regions 224 and 225 of memory cells 200 in the same column. As shown in FIGS. 4A and 4B, all memory cells 200 of memory array 400 share one sub-gate 218.

FIGS. 4C-4G illustrate operations of memory array 400. In FIG. 4C, memory array 400 is reset or erased by biasing word lines WL at, e.g., −18V, while semiconductor substrate 202 is grounded (not shown). Diffusion regions 402 and 404 of the bit lines BL are grounded. Sub-gate 218 is biased at a negative voltage, e.g., −10V. In FIG. 4D, the first bit of memory cell 2003 is programmed by biasing the corresponding word line, WL1, at, e.g., 6V, diffusion region 402 of the corresponding bit line, BL3, at, e.g., −6V, diffusion regions 402 of all other bit lines BL and diffusion regions 404 of all the bit lines BL at, e.g., 0V, all other word lines WL at, e.g., −5V, and sub-gate 218 at, e.g., −10V. In FIG. 4E, the second bit of memory cell 200₃ is programmed by biasing the corresponding word line, WL1, at, e.g., 6V, diffusion region 404 of the corresponding bit line, BL3, at, e.g., −6V, diffusion regions 404 of all other bit lines BL and diffusion regions 402 of all the bit lines BL at, e.g., 0V, all other word lines WL at, e.g., −5V, and sub-gate 218 at, e.g., −10V. In FIG. 4F, the first bit of memory cell 200₃ is read by biasing the corresponding word line, WL1, at, e.g., 5V, diffusion region 404 of the corresponding bit line, BL3, at, e.g., −2V, diffusion regions 404 of all other bit lines BL and diffusion regions 402 of all the bit lines BL at, e.g., 0V, and all other word lines WL and sub-gate 218 at, e.g., −5V. In FIG. 4G, the second bit of memory cell 200₃ is read by biasing the corresponding word line, WL1, at, e.g., 5V, diffusion region 402 of the corresponding bit line, BL3, at, e.g., −2V, diffusion regions 402 of all other bit lines BL and diffusion regions 404 of all the bit lines BL at, e.g., 0V, and all other word lines WL and sub-gate 218 at, e.g., −5V.

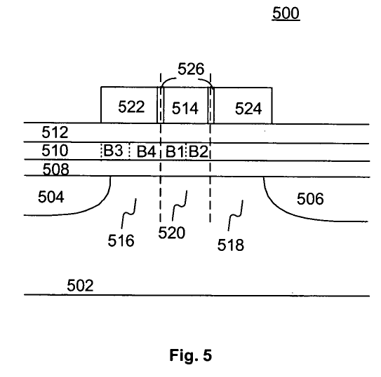

Consistent with a third embodiment of the present invention, a multi-bit memory cell is provided. FIG. 5 shows a multi-bit memory cell 500 formed on a semiconductor substrate 502 including diffusion regions 504 and 506. Semiconductor substrate 502 may comprise an n-type semiconductor material, such as n-type silicon. Diffusion regions 504 and 506 are doped with p-type impurities. A first insulating layer 508, a trapping layer 510, and a second insulating layer 512 are sequentially formed on semiconductor substrate 502. First insulating layer 508 may comprise silicon dioxide, trapping layer 510 may comprise silicon nitride, and second insulating layer 512 may comprise silicon dioxide. A control gate 514 is formed on second insulating layer 512 and is between and spaced apart from diffusion regions 504 and 506. Control gate 514 may comprise polysilicon, a metal, or metal silicide, or a combination thereof. For example, control gate 514 may comprise a combination of polysilicon and tungsten silicide (WSi). Memory cell 500 also includes two inversion regions 516 and 518 and a channel region 520. Inversion region 516 is defined as the portion of semiconductor substrate 502 between diffusion region 504 and control gate 514, inversion region 518 is defined as the portion of semiconductor substrate 502 between diffusion region 506 and control gate 514, and channel region 520 is defined as the portion of semiconductor substrate 502 between inversion regions 516 and 518, i.e., below control gate 514. Memory cell 500 further includes two sub-gates 522 and 524 provided on second insulating layer 512 and respectively over inversion regions 516 and 518. Sub-gates 522 and 524 may comprise polysilicon, a metal, or metal silicide, or a combination thereof. Sub-gates 522 and 524 are electrically isolated from control gate 514 by insulating spacers 526.

As shown in FIGS. 2 and 5, memory cell 500 differs from memory cell 200 in two aspects: first, gate dielectric 220 of memory cell 200 is now replaced with first insulating layer 508, trapping layer 510, and second insulating layer 512; second, sub-gate 218 is now divided into two sub-gates 522 and 524. With the configuration shown in FIG. 5, memory cell 500 may be operated to store more than two bits of information.

In one aspect, a first bit B1 may be stored in the left side of the portion of trapping layer 510 under control gate 514, a second bit B2 may be stored in the right side of the portion of trapping layer 510 under control gate 514, a third bit B3 may be stored in the left side of the portion of trapping layer 510 under sub-gate 522, and a fourth bit B4 may be stored in the right side of the portion of trapping layer 510 under sub-gate 522. One skilled in the art should now appreciate the operations of memory cell 500, i.e., the operations for reading, programming, and erasing the first to fourth bits of memory cell 500. For example, to read the second bit B2, diffusion region 504 is grounded, diffusion region 506 is biased at, e.g., −2V, control gate 514 is biased at, e.g., 3V, and sub-gates 522 and 524 are biased at, e.g., −5V. To program the third bit B3, both control gate 514 and sub-gate 524 are biased at, e.g., −5V, sub-gate 522 is biased at, e.g., 6V, diffusion region 504 is based at, e.g., −6V, and diffusion region 506 is grounded. To erase memory cell 500, a high negative voltage, such as −18V, is applied to control gate 514 and sub-gates 522 and 524, while substrate 502 is grounded.

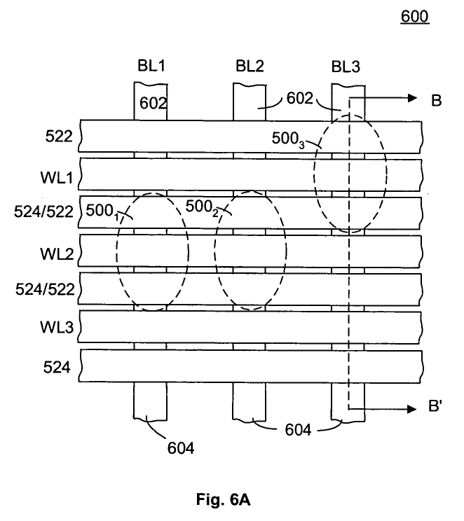

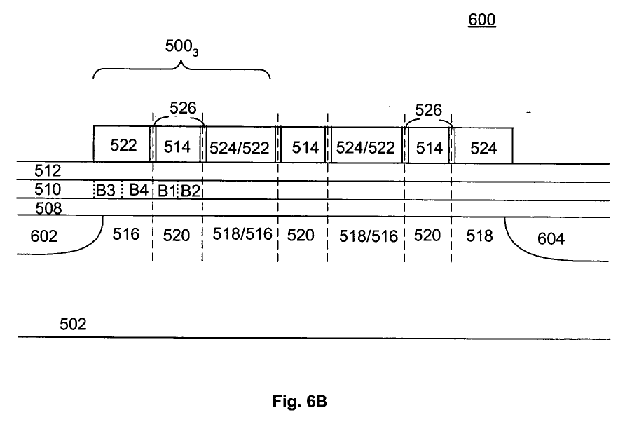

Consistent with a fourth embodiment of the present invention, a plurality of memory cells 500 (500₁, 500₂, 500₃, . . . ) may be arranged to form a memory array, such as memory array 600 in FIGS. 6A and 6B. FIG. 6A is a plan view of memory array 600 and FIG. 6B is a cross-sectional view of memory array 600 along line B-B′. As shown in FIG. 6A, memory array 600 has a plurality of rows each corresponding to a word line WL (WL1, WL2, WL3, . . . ) and a plurality of columns each corresponding to a bit line BL (BL1, BL2, BL3, . . . ). Control gate 514 of memory cells 500 in the same row are connected together and constitute the corresponding word line WL. Each bit line includes two diffusion regions 602 and 604 at the ends thereof, and also includes inversion regions 516 and 518 of memory cells 500 in the same column. Unlike memory array 400, sub-gates 522 and 524 of memory cells 500 in the same column of memory array 600 are not connected together. As compared to memory array 400, memory array 600 has a higher storage density.

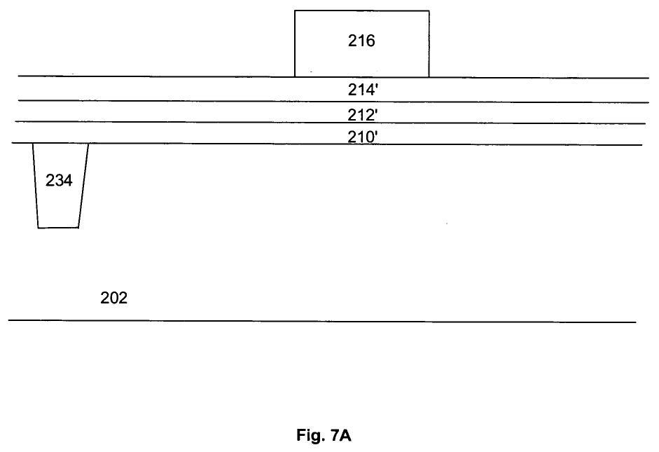

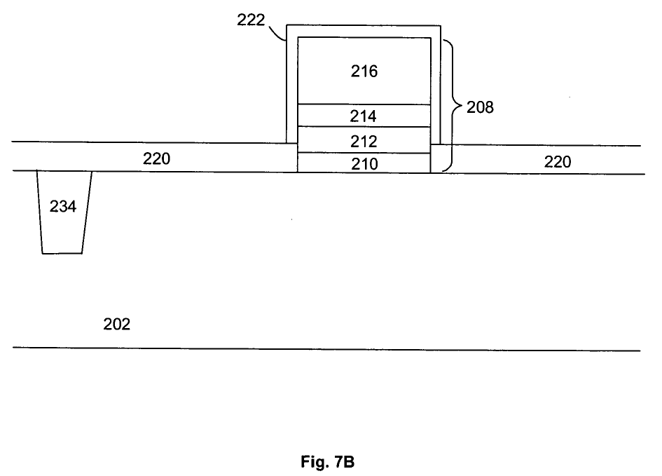

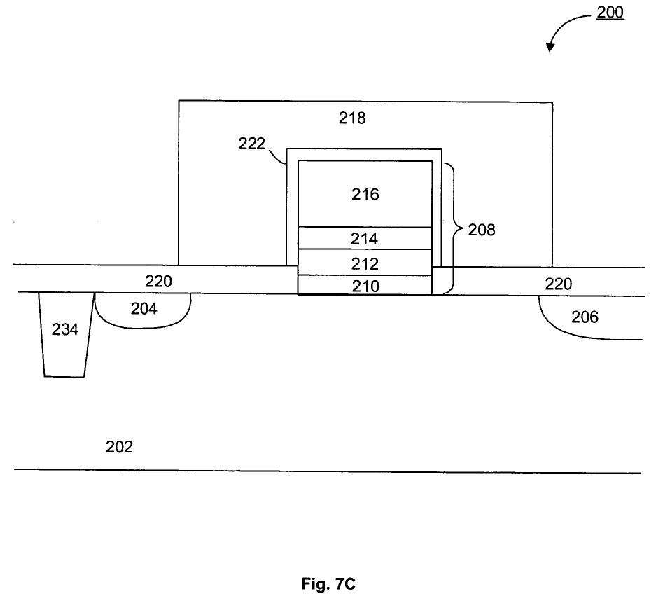

Memory devices consistent with embodiments of the present invention may be formed using typical MOS fabrication techniques. A process for manufacturing memory cell 200 is described with reference to FIGS. 7A-7C.

First, in FIG. 7A, after device isolation regions 234 (only one of which is shown) such as shallow trench isolations are formed for defining device regions, a first oxide layer 210′, a nitride layer 212′, and a second oxide layer 214′ are sequentially deposited on silicon substrate 202. A layer of polysilicon or metal is deposited on second oxide layer 214′ and patterned to form control gate 216.

In FIG. 7B, first oxide layer 210′, nitride layer 212′, and second oxide layer 214′ are etched to form an ONO structure composed of first oxide layer 210, nitride layer 212, and second oxide layer 214, using control gate 216 as a mask. A layer of oxide is then deposited to form gate dielectric 220. Insulating spacer 222 may be formed simultaneously.

In FIG. 7C, a layer of polysilicon or metal is deposited and patterned to form sub-gate 218, followed by ion implantation and diffusion to form diffusion regions 204 and 206.

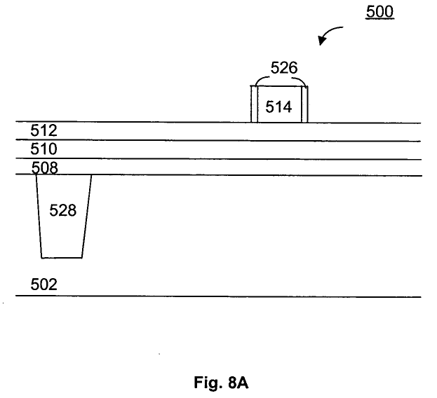

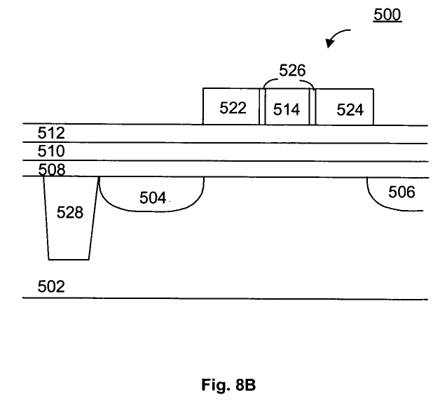

A manufacturing process of memory cell 500 is described with reference to FIGS. 8A-8B.

First, in FIG. 8A, after device isolation regions 528 (only one of which is shown) such as shallow trench isolations are formed for defining device regions, first oxide layer 508, nitride layer 510, and second oxide layer 512 are sequentially deposited on silicon substrate 502. Control gate 514 is formed by depositing and patterning a layer of polysilicon or metal. Spacers 526 are formed on sidewalls of control gate 514.

Then, in FIG. 8B, a layer of polysilicon or metal is deposited and patterned to form sub-gates 522 and 524, followed by ion implantation and diffusion to form diffusion regions 504 and 506.

A memory device comprising memory cells consistent with embodiments of the present invention has advantages over conventional memory devices because inversion regions are used in the place of diffusion regions, so that problems associated with ion implantation and boron diffusion in short channel MOS devices are obviated. Memory devices consistent with embodiments of the present invention also have advantages of a p-type MOS transistor that utilizes BTBTHE, such as high efficiency of carrier injection, high speed, better data retention properties than conventional memory devices, and immunity to plasma radiation, etc.

It will be apparent to those skilled in the art that various modifications and variations can be made in the disclosed process without departing from the scope or spirit of the invention. Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A semiconductor device, comprising:
a semiconductor substrate, including
a first inversion region,
a second inversion region, and
a channel region between the first inversion region and the second inversion region;
a control gate over the channel region; and
at least one sub-gate over the first and second inversion regions, wherein the control gate does not extend over the at least one sub-gate.

2. The device of claim 1, wherein the semiconductor substrate is n-type.

3. The device of claim 1, wherein the control gate comprises polysilicon, a metal, or a metal silicide, or a combination thereof.

4. The device of claim 1, further comprising:
a first insulating layer on the channel region;
a trapping layer on the first insulating layer; and
a second insulating layer on the trapping layer,
wherein the control gate is on the second insulating layer.

5. The device of claim 1, wherein the at least one sub-gate comprises polysilicon, a metal, or a metal silicide, or a combination thereof.

6. The device of claim 1, further comprising a layer of gate dielectric between the at least one sub-gate and the first and second inversion regions.

7. The device of claim 1, wherein the at least one sub-gate comprises one sub-gate over the first inversion region, the second inversion region, and the control gate.

8. The device of claim 1, further comprising:
a first insulating layer on the channel region and the first and second inversion regions;
a trapping layer on the first insulating layer; and
a second insulating layer on the trapping layer,
wherein the at least one sub-gate comprises a first sub-gate over the first inversion region and a second sub-gate over the second inversion region, and wherein the first sub-gate, the second sub-gate, and the control gate are all on the second insulating layer.

9. A memory device, comprising:
a semiconductor substrate;
a plurality of memory cells arranged in a plurality of rows each corresponding to one of a plurality of word lines and a plurality of columns each corresponding to one of a plurality of bit lines, each memory cell comprising:
a first inversion region of the semiconductor substrate,
a second inversion region of the semiconductor substrate,
a channel region defined as a portion of the semiconductor substrate between the first and second inversion regions,
a control gate over the channel region, and
at least one sub-gate over the first and second inversion regions,
wherein the first inversion region and the second inversion region are along a direction of the corresponding one of the bit lines, and each word line connects the control gates of the memory cells in the same row;
a plurality of diffusion regions, wherein each bit line includes two of the diffusion regions at the ends of the corresponding bit line.

10. The device of claim 9, wherein the semiconductor substrate is n-type, and the diffusion regions are p-type.

11. The device of claim 9, wherein the control gates of the memory cells comprise polysilicon, a metal, or a metal silicide, or a combination thereof.

12. The device of claim 9, each memory cell further comprising:
a first insulating layer on the channel region;
a trapping layer on the first insulating layer; and
a second insulating layer on the trapping layer,
wherein the control gate is on the second insulating layer.

13. The device of claim 9, wherein the at least one sub-gate of the memory cells comprise polysilicon, a metal, or a metal silicide, or a combination thereof.

14. The device of claim 9, each memory cell further comprising a layer of gate dielectric between the at least one sub-gate and the first and second inversion regions.

15. The device of claim 9, the at least one sub-gate of each memory cell comprises one sub-gate over both the first and second inversion regions.

16. The device of claim 9, each memory cell further comprising:
a first insulating layer on the channel region and the first and second inversion regions;
a trapping layer on the first insulating layer; and
a second insulating layer on the trapping layer,
wherein the at least one sub-gate comprises a first sub-gate over the first inversion region and a second sub-gate over the second inversion region, and wherein the first sub-gate, the second sub-gate, and the control gate are all on the second insulating layer.

17. The device of claim 9, wherein the sub-gates of the memory cells are electrically connected to one another and each memory cell is capable of storing two bits of information.

18. The device of claim 9, wherein adjacent ones of the memory cells share the at least one sub-gate thereof.

19. The device of claim 9, wherein adjacent ones of the memory cells on the same bit line share one of the first and second inversion regions.

20. The device of claim 9, wherein the at least one sub-gate of each memory cell comprises a first sub-gate over the corresponding first inversion region and a second sub-gate over the corresponding second inversion region, and wherein each memory cell is capable of storing four bits of information.

21. A method of operating a memory cell, wherein the memory cell is formed on an n-type semiconductor substrate, wherein the memory cell includes a first inversion region and a second inversion region in the semiconductor substrate, a channel region in the semiconductor substrate between the first inversion region and the second inversion region, a control gate over the channel region, and at least one sub-gate over the first and second inversion regions, wherein the control gate does not extend over the at least one sub-gate, the method comprising:
at least one of resetting the memory cell, erasing the memory cell, programming the memory cell, and reading the memory cell.

22. The method of claim 21, wherein resetting and erasing the memory cell comprises:
applying a high negative voltage on the control gate, and
grounding the semiconductor substrate.

23. The method of claim 21, wherein the memory cell includes a first bit region and a second bit region each for storing one bit of information, the first bit region corresponding to the first inversion region and the second bit region corresponding to the second inversion region, wherein programming the memory cell comprises programming the first bit region or the second bit region,
wherein programming the first bit region includes
applying a positive voltage on the control gate,
applying a first negative voltage on the at least one sub-gate,
applying a second negative voltage on the first inversion region, and
grounding the second inversion region and the semiconductor substrate, and
wherein programming the second bit region includes
applying the positive voltage on the control gate,
applying the first negative voltage on the at least one sub-gate,
applying the second negative voltage on the second inversion region, and
grounding the first inversion region and the semiconductor substrate.

24. The method of claim 23, wherein applying the first negative voltage comprises applying the first negative voltage such that p-type regions are created in the first and second inversion regions.

25. The method of claim 21, wherein the memory cell includes a first bit region and a second bit region each for storing one bit of information, the first bit region corresponding to the first inversion region and the second bit region corresponding to the second inversion region, wherein reading the memory cell comprising reading the first bit region or the second bit region,
wherein reading the first bit region includes
applying a positive voltage on the control gate,
applying a first negative voltage on the at least one sub-gate,
applying a second negative voltage on the second inversion region, and
grounding the first inversion region and the semiconductor substrate, and
wherein reading the second bit region includes
applying the positive voltage on the control gate,
applying the first negative voltage on the at least one sub-gate,
applying the second negative voltage on the first inversion region, and
grounding the second inversion region and the semiconductor substrate.

26. The method of claim 25, wherein applying the first negative voltage comprises applying the first negative voltage such that p-type regions are created in the first and second inversion regions.

27. The method of claim 25, wherein applying the positive voltage, the first negative voltage, and the second negative voltage comprises applying said voltages such that a p-type channel is created in a portion of the channel region adjacent to the first inversion region when the first bit region is read and if the first bit region is in a programmed state, and a p-type channel is created in a portion of the channel region adjacent to the second inversion region when the second bit region is read and if the second bit region is in a programmed state.

28. The method of claim 21,
wherein the memory cell further comprises a first insulating layer on the channel region and the first and second inversion regions, a trapping layer on the first insulating layer, and a second insulating layer on the trapping layer,
wherein the at least one sub-gate comprises a first sub-gate over the first inversion region and a second sub-gate over the second inversion region,
wherein the first sub-gate, the second sub-gate, and the control gate are all on the second insulating layer,
wherein the memory cell includes a first bit region, a second bit region, a third bit region, and a fourth bit region, each of the first bit region, the second bit region, the third bit region, and the fourth bit region for storing one bit of information, the first bit region corresponding to a first part of a first portion of the trapping layer under the control gate, the second bit region corresponding to a second part of the first portion of the trapping layer, the third bit region corresponding to a first part of a second portion of the trapping layer under the first sub-gate, the fourth bit region corresponding to a second part of the second portion of the trapping layer,
wherein programming the memory cell comprising programming the first bit region, the second bit region, the third bit region, or the fourth bit region, and
wherein reading the memory cell comprising reading the first bit region, the second bit region, the third bit region, or the fourth bit region.

29. A method of operating a memory device, wherein the memory device is formed on an n-type semiconductor substrate and includes a plurality of memory cells arranged in a plurality of rows each corresponding to one of a plurality of word lines and a plurality of columns each corresponding to one of a plurality of bit lines, each memory cell including a first inversion region of the semiconductor substrate, a second inversion region of the semiconductor substrate, a channel region defined as a portion of the semiconductor substrate between the first and second inversion regions, a control gate over the channel region, and at least one sub-gate over the first and second inversion regions, wherein the first inversion region and the second inversion region are along a direction of the corresponding one of the bit lines, and wherein each word line connects the control gates of the memory cells in the same row, the memory device further including a plurality of diffusion regions, wherein each bit line includes two of the diffusion regions at the ends of the corresponding bit line, the method comprising:
at least one of resetting the memory device, erasing the memory device, programming a selected memory cell, and reading a selected memory cell.

30. The method of claim 29, wherein resetting or erasing the memory cell comprises:
applying a high negative voltage on the word lines, and
grounding the semiconductor substrate.

31. The method of claim 29, wherein each memory cell includes a first bit region and a second bit region each for storing one bit of information, the first bit region corresponding to the first inversion region and one of the two diffusion regions of the corresponding bit line, and the second bit region corresponding to the second inversion region and the other of the two diffusion regions of the corresponding bit line, wherein programming a selected memory cell comprises programming the first bit region or the second bit region of the selected memory cell,
wherein programming the first bit region of the selected memory cell includes
applying a positive voltage on the word line corresponding to the selected memory cell,
applying a first negative voltage on all other word lines and the sub-gates of all the memory cells,
applying a second negative voltage on the one of the two diffusion regions of the corresponding bit line, and
grounding all other diffusion regions of the memory device and the semiconductor substrate, and
wherein programming the second bit region of the selected memory cell includes
applying the positive voltage on the word line corresponding to the selected memory cell,
applying the first negative voltage on all other word lines and the sub-gates of all the memory cells,
applying the second negative voltage on the other of the two diffusion regions of the corresponding bit line, and
grounding all other diffusion regions of the memory device and the semiconductor substrate.

32. The method of claim 31, wherein applying the first negative voltage comprises applying the first negative voltage such that p-type regions are created in the corresponding first inversion regions, second inversion regions, and channel regions of the memory cells.

33. The method of claim 29, wherein each memory cell includes a first bit region and a second bit region each for storing one bit of information, the first bit region corresponding to the first inversion region and one of the two diffusion regions of the corresponding bit line, and the second bit region corresponding to the second inversion region and the other of the two diffusion regions of the corresponding bit line, wherein reading a selected memory cell comprises reading the first bit region or the second bit region of the selected memory cell,
wherein reading the first bit region of the selected memory cell includes
applying a positive voltage on the word line corresponding to the selected memory cell,
applying a first negative voltage on all other word lines and the sub-gates of all the memory cells,
applying a second negative voltage on the other of the two diffusion regions of the corresponding bit line, and
grounding all other diffusion regions of the memory device and the semiconductor substrate, and
wherein reading the second bit region of the selected memory cell includes
applying the positive voltage on the word line corresponding to the selected memory cell,
applying the first negative voltage on all other word lines and the sub-gates of all the memory cells,
applying the second negative voltage on the one of the two diffusion regions of the corresponding bit line, and
grounding all other diffusion regions of the memory device and the semiconductor substrate.

34. The method of claim 33, wherein applying the first negative voltage comprises applying the first negative voltage such that p-type regions are created in the corresponding first inversion regions, second inversion regions, and channel regions of the memory cells.

35. The method of claim 33, wherein applying the positive voltage, the first negative voltage, and the second negative voltage comprises applying the positive voltage, the first negative voltage, and the second negative voltage such that a p-type channel is created in a portion of the channel region of the selected memory cell adjacent to the first inversion region of the selected memory cell when the first bit region of the selected memory cell is read and if the first bit region of the selected memory cell is in a programmed state, and a p-type channel is created in a portion of the channel region of the selected memory cell adjacent to the second inversion region of the selected memory cell when the second bit region of the selected memory cell is read and if the second bit region of the selected memory cell is in a programmed state.

36. The method of claim 29,
wherein each memory cell further comprises a first insulating layer on the channel region and the first and second inversion regions, a trapping layer on the first insulating layer, and a second insulating layer on the trapping layer,
wherein the at least one sub-gate comprises a first sub-gate over the first inversion region and a second sub-gate over the second inversion region,
wherein the first sub-gate, the second sub-gate, and the control gate are all on the second insulating layer,
wherein each memory cell includes a first bit region, a second bit region, a third bit region, and a fourth bit region, each of the first bit region, the second bit region, the third bit region, and the fourth bit region for storing one bit of information, the first bit region corresponding to a first part of a first portion of the trapping layer under the control gate, the second bit region corresponding to a second part of the first portion of the trapping layer, the third bit region corresponding to a first part of a second portion of the trapping layer under the first sub-gate, the fourth bit region corresponding to a second part of the second portion of the trapping layer,
wherein programming the selected memory cell comprising programming the first bit region, the second bit region, the third bit region, or the fourth bit region of the selected memory cell, and
wherein reading the selected memory cell comprising reading the first bit region, the second bit region, the third bit region, or the fourth bit region of the selected memory cell.
